(19) United States
(12) Patent Application Publication
(10) Pub. No.: US 2014/0151700 A1
(43) Pub. Date: Jun. 5, 2014

(54) CHIP PACKAGE AND A METHOD FOR MANUFACTURING A CHIP PACKAGE

(71) Applicants: Thorsten Meyer, Regensburg (DE); Markus Brunnbauer, Lappersdorf (DE); Bernd Waidhas, Pettendorf (DE)

(72) Inventors: Thorsten Meyer, Regensburg (DE); Markus Brunnbauer, Lappersdorf (DE); Bernd Waidhas, Pettendorf (DE)

(21) Appl. No.: 13/693,109

(22) Filed: Dec. 4, 2012

(51) Int. Cl. H01L 23/544; H01L 21/48

(52) U.S. Cl. CPC H01L 23/544; H01L 21/4853
USPC 257/48; 438/613

(57) ABSTRACT

A chip package may include an interconnection layer having a first surface configured to face at least one chip, and a second surface opposite the first surface; at least one first pad and at least one second pad formed at at least one of the first surface and the second surface of the interconnection layer; at least one first conductive interconnect formed over the at least one first pad; and at least one second conductive interconnect formed over the at least one second pad, wherein a height of the at least one first conductive interconnect is less than a height of the at least one second conductive interconnect.

### TECHNICAL FIELD

Various aspects relate to chip packages and methods for manufacturing a chip package.

### BACKGROUND

A chip package (e.g. for MEMS, logic, memory and/or power applications) may require electrical testing to assess basic functions of the chip package. The chip package may be connected to an end-user board after testing. A high test quality, a high measure of repeatability for testing the chip package, and increased area for circuit routing in the end-user board may be needed. The chip package may include contacts (e.g. pins, solder balls) which may be used for testing. Some of the contacts may not be used when the chip package is connected to the end-user board. Nonetheless, landing pads may need to be provided on the end-user board for these contacts even if such contacts do not provide an additional benefit. This may lead to a waste of real estate on the end-user board.

### SUMMARY

A chip package is provided which may include: an interconnection layer having a first surface configured to face at least one chip, and a second surface opposite the first surface; at least one first pad and at least one second pad formed at at least one of the first surface and the second surface of the interconnection layer; at least one first conductive interconnect formed over the at least one first pad; and at least one second conductive interconnect formed over the at least one second pad, wherein a height of the at least one first conductive interconnect is less than a height of the at least one second conductive interconnect.

A method for manufacturing a chip package is provided which may include: providing an interconnection layer having a first surface configured to face at least one chip, and a second surface opposite the first surface; forming at least one first pad and at least one second pad at at least one of the first surface and the second surface of the interconnection layer; forming at least one first conductive interconnect over the at least one first pad; and forming at least one second conductive interconnect over the at least one second pad, wherein a height of the at least one first conductive interconnect is less than a height of the at least one second conductive interconnect.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A and FIG. 1B show cross-sectional views of a conventional chip package and a customer board.

FIG. 2A and FIG. 2B show cross-sectional views of a chip package where test pads are free from test solder balls, and where a customer board is free from landing pads for test solder balls.

FIG. 3 shows a cross-sectional view of a chip package.

FIG. 4 and FIG. 5 show cross-sectional views of a chip package including at least one chip, a chip-mounting region, and a chip-external connection region.

FIG. 5 shows a cross-sectional view of a chip package including at least one chip and a chip-mounting region.

FIG. 6 shows a method for manufacturing a chip package.

FIG. 7A to FIG. 7E show various views illustrating a method for manufacturing a chip package including non-selective deposition of a first conductive material.

FIG. 8A to FIG. 8E show various views illustrating a method for manufacturing a chip package including selective deposition of a first conductive material.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects can be combined with one or more other aspects to form new aspects. Various aspects are described for structures or devices, and various aspects are described for methods. It may be understood that one or more (e.g. all) aspects described in connection with structures or devices may be equally applicable to the methods, and vice versa.

The word “exemplary” is used herein to mean “serving as an example, instance, or illustration”. Any aspect or design described herein as “exemplary” is not necessarily to be construed as preferred or advantageous over other aspects or designs.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

In like manner, the word “cover”, used herein to describe a feature disposed over another, e.g. a layer “covering” a side or surface, may be used to mean that the feature, e.g. the layer, may be disposed over, and in direct contact with, the implied side or surface. The word “cover”, used herein to describe a feature disposed over another, e.g. a layer “covering” a side or surface, may be used to mean that the feature, e.g. the layer, may be disposed over, and in indirect contact with, the implied side or surface with one or more additional layers being arranged between the implied side or surface and the covering layer.

The terms “coupled” and/or “electrically coupled” and/or “connected” and/or “electrically connected”, used herein to describe a feature being connected to at least one other implied feature, are not meant to mean that the feature and the at least one other implied feature must be directly coupled or connected together; intervening features may be provided between the feature and at least one other implied feature.

Directional terminology, such as e.g. “upper”, “lower”, “top”, “bottom”, “left-hand”, “right-hand”, etc., may be used with reference to the orientation of figure(s) being described. Because components of the figure(s) may be positioned in a number of different orientations, the directional terminology is used for purposes of illustration and is in no way limiting. It is to be understood that structural or logical changes may be made without departing from the scope of the invention.

A chip package (e.g. for MEMS, logic, memory and/or power applications) may require electrical testing to assess basic functions of the chip package. For example, the chip package may include at least one chip (e.g. a logic chip). Testing of the chip package may include testing the characteristics of the at least one chip (e.g. rise time and/or slew rate tests) to, for example, ensure that the chip package is functioning according to specification. Testing of the chip package may also include configuring settings for the at least one chip (e.g. to improve performance of a chip, e.g. increase computation speed of the chip).

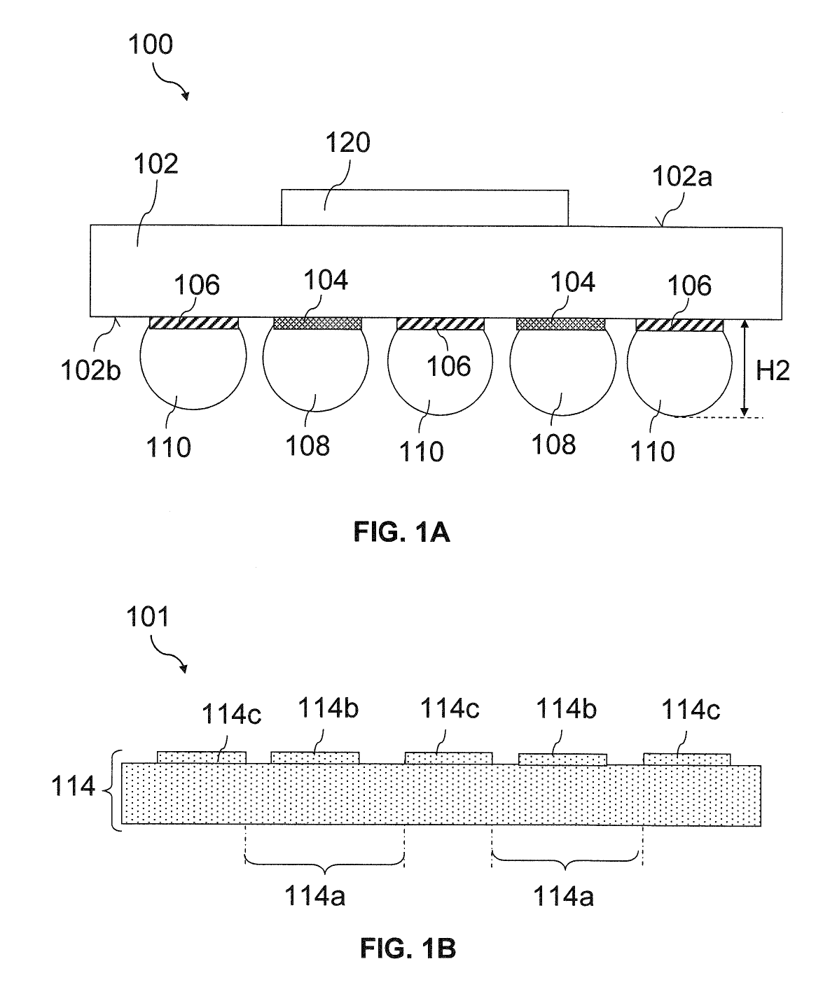

FIG. 1A shows a cross-sectional view of a conventional chip package 100.

As shown in FIG. 1A, the chip package 100 may include an interconnection layer 102 having a first surface 102a and a second surface 102b. The chip package 100 may include at least one chip 120 disposed over a surface (e.g. the first surface 102a) of the interconnection layer 102. Disposing the at least one chip 120 over the surface (e.g. over the first surface 102a) of the interconnection layer 120 may including bonding the at least one chip 120 to the surface (e.g. the first surface 102a) of the interconnection layer 102. For example, the interconnection layer 102 may include, or may be, a carrier (e.g. a ceramic carrier). Accordingly, the at least one chip 120 may be bonded to the surface of the interconnection layer 102 by means of a wire-bonding method, a flip-chip bonding method or other suitable bonding methods. By way of another example, the at least one chip 120 may be part of a wafer level BGA (ball grid array) package (which may also be referred to as WLB package). Accordingly, the interconnection layer 102 may include, or may be, a redistribution layer (e.g. a thin-film redistribution layer).

The chip package 100 may include at least one test pad 104 configured to receive at least one test signal. The at least one test pad 104 may be used only for the purposes of testing the chip package 100. Accordingly, the at least one test pad 104 may not be needed in an end-user application. In other words, the at least one test pad 104 may not be used to exchange end-user signals.

The chip package 100 may include at least one application pad 106 (e.g. a pad that may be used to exchange end-user signals). In other words, the at least one application pad 106 may be needed in a customer application (i.e. an end-user application). The at least one application pad 106 may additionally be used for testing the chip package 100. Therefore, the at least one application pad 106 may additionally be configured to receive at least one test signal. However, in contrast to the at least one test pad 104, the at least one application pad 106 may also be needed in an end-user application. In other words, the at least one application pad 106 may be used for more than just testing the chip package 100.

The chip package 100 may include a plurality of solder balls 108, 110 formed over the at least one test pad 104 and the at least one application pad 106. For example, at least one test solder ball 108 may be formed over the at least one test pad 104, and at least one application solder ball 110 may be formed over the at least one application pad 106. As shown in FIG. 1A, the at least one test solder ball 108 may have substantially the same size and/or substantially the same height as the at least one application solder ball 110.

FIG. 1B shows a cross-sectional view 101 of a customer board 114 (e.g. a printed circuit board) used in an end-user application including a plurality of landing pads 114b, 114c.

As shown in FIG. 1B, the customer board 114 may include at least one test landing pad 114b configured to connect to the at least one test solder ball 108, and at least one application landing pad 114c configured to connect to the at least one application solder ball 110.

As described above, the at least one test pad 104 may not be used and/or needed in an end-user application. However, the customer board 114 may require the at least one test landing pad 114b for the at least one test solder ball 108, even if the at least one test pads 104 and/or at least one test solder ball 108 do not provide additional benefit. Therefore, the at least one test landing pad 114b may occupy an area 114a on the customer board 114. Consequently, the area 114a, which may be occupied by the at least one test landing pad 114b, may not be used for circuitry used in the end-user application. For example, the area 114a may not be used for routing circuitry that may be useful for the end-user application. This may result in the use of a more complex customer board 114. For example, the customer board 114 may require more layers for routing circuitry. By way of another example, design of circuitry in the customer board 114 may require more complex design methods.

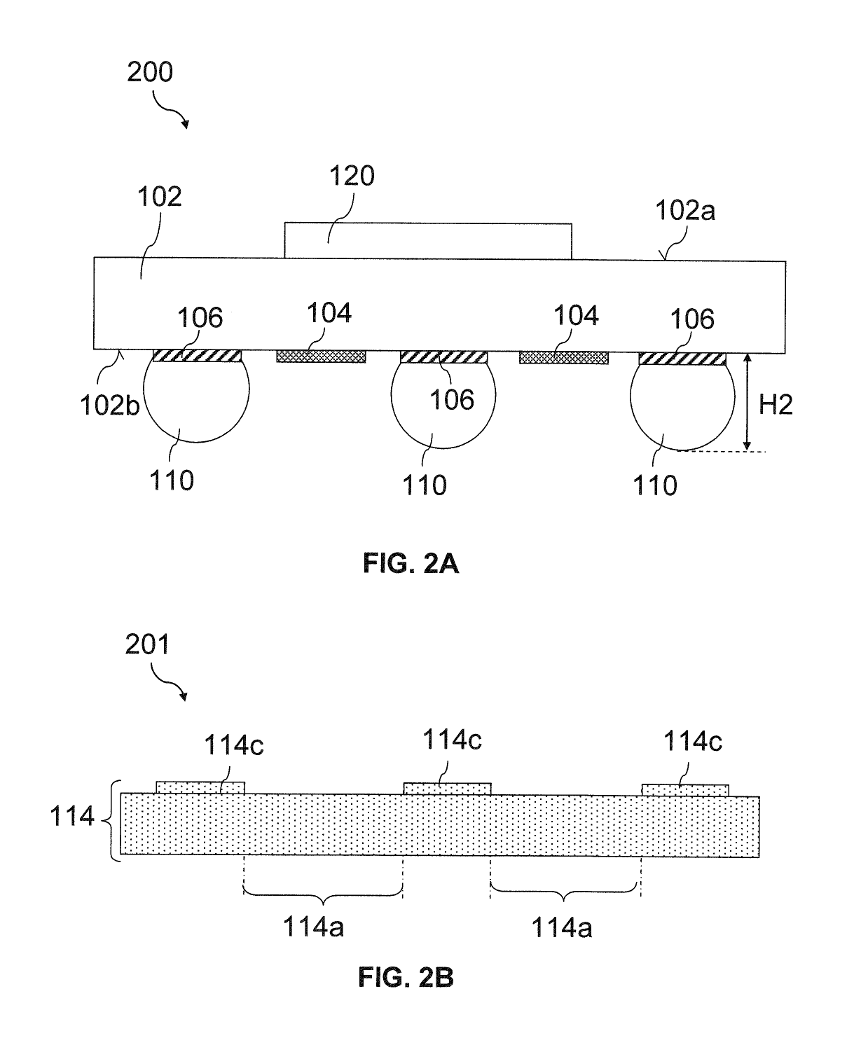

FIG. 2A shows a cross-sectional view of a chip package 200 where the at least one test pad is free from test solder balls.

Reference signs in FIG. 2A and FIG. 2B that are the same as in FIG. 1A and FIG. 1B denote the same or similar elements as in FIG. 1A and FIG. 1B. Thus, those elements will not be described in detail again here; reference is made to the description above. Differences between FIGS. 2A to 2B and FIGS. 1A to 1B are described below.

As shown in FIG. 2A, the chip package 200 may include at least one application solder ball 110 formed over the at least one application pad 106, and the at least one test pad 104 may be free from a test solder ball. For example, Song et al., “Semiconductor Package Having Test Pads on Top and Bottom Substrate Surfaces and Method of Testing Same” U.S. patent application publication number US 2012/0105089 A1, published on May 3, 2012, describes a chip package where test pads are free from test solder balls. A result of the at least one test pad 104 being free from a test solder ball may be that the customer board 114 may have an area 114a that may be free from test landing pads, as shown in FIG. 2B in a view 201. This may allow the area 114a to be used for routing circuitry that may be useful for the end-user application. However, there may be adverse effects of having such an arrangement.

For example, as described above, the at least one test pad 104 and the at least one application pad 106 may be used for testing the chip package 200. Accordingly, testing equipment (e.g. probes of a test card) may make contact with the at least one test pad 104 and the at least one application solder ball 110 formed over the at least one application pad 106. The at least one test pad 104 and the at least one application solder ball 110 may include, or may consist of, different materials. Therefore, a contact resistance between the testing equipment (e.g. test probes) and the at least one test pad 104 may be different from a contact resistance between the testing equipment (e.g. test probes) and the at least one application solder ball 110. Accordingly, testing may be done on surfaces having different contact resistances, which may adversely affect the quality of the testing. For example, the test quality of the chip package 200 where the at least one test pad 104 is free from a test solder ball may not be high and/or testing of the chip package 200 may not achieve a high measure of repeatability.

Further, since different structures of the chip package 200 may being tested, there may be a need for different test contact mechanisms and/or test structures to be used. For example, the test equipment (e.g. test card) may require one test structure and/or mechanism to make contact with the at least one test pad 104, and another test structure and/or mechanism to make contact with the at least one application solder ball 110. This may increase the complexity of the testing equipment.

In addition, the at least one test pad 104 of the chip package 200 may be exposed since the at least one test pad 104 is free from a test solder ball. The at least one test pad 104 may include, or may consist of, a material (e.g. copper, for example in mobile applications) that may be easily corroded. Corrosion of the test pad (e.g. copper test pad) may adversely affect test quality and test repeatability. A possible solution to this may be the use of corrosion resistant layer (e.g. a copper-nickel-gold (Cu—Ni—Au) layer) on the at least one test pad 104. However, different surfaces may still be tested, namely, a corrosion resistant layer (e.g. Cu—Ni—Au surface) for the at least one test pad 104, and solder for the at least one application pad 106. Further, forming a corrosion resistant layer (e.g. a Cu—Ni—Au layer) on the at least one test pad 104 may not be preferred for mobile applications due to higher cost and a weakness in the drop test, which may be an important test for mobile applications.

Accordingly, it may be desirable to achieve high test quality and a high measure of repeatability for testing a chip package, whilst providing increased space for circuit routing in an end-user board.

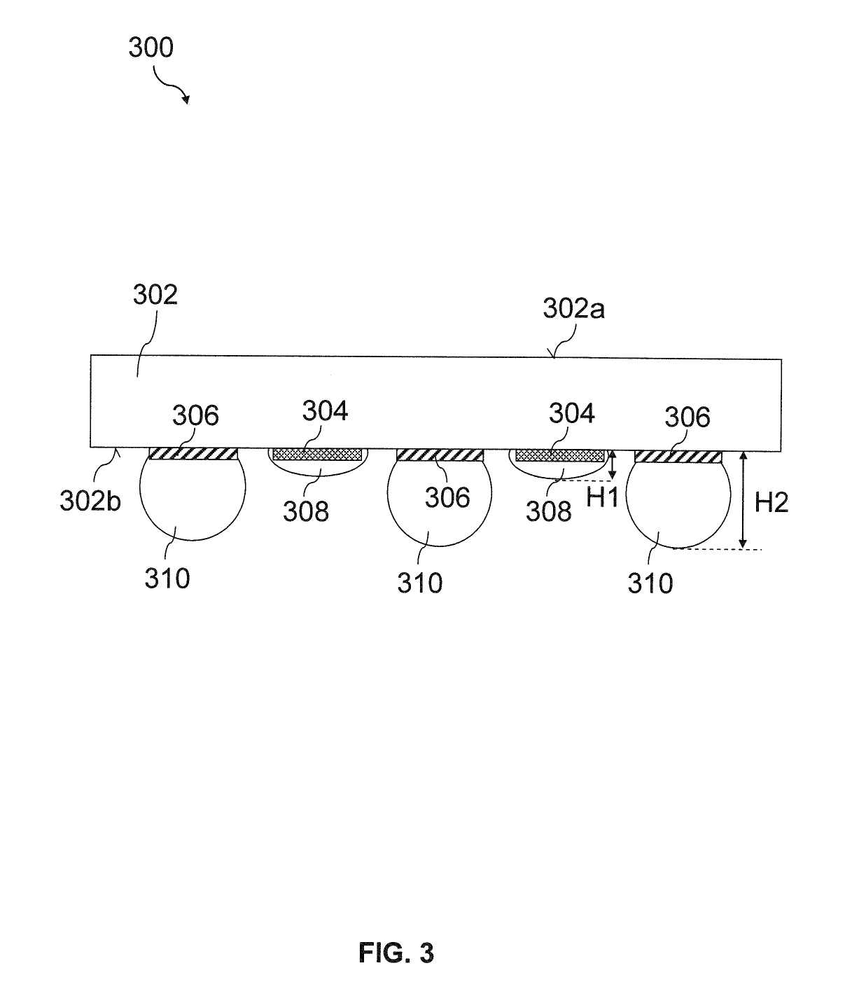

FIG. 3 shows a cross-sectional view of a chip package 300.

The chip package 300 may include an interconnection layer 302, at least one first conductive interconnect 308 formed over at least one first pad 304, and at least one second conductive interconnect 310 formed over at least one second pad 306.

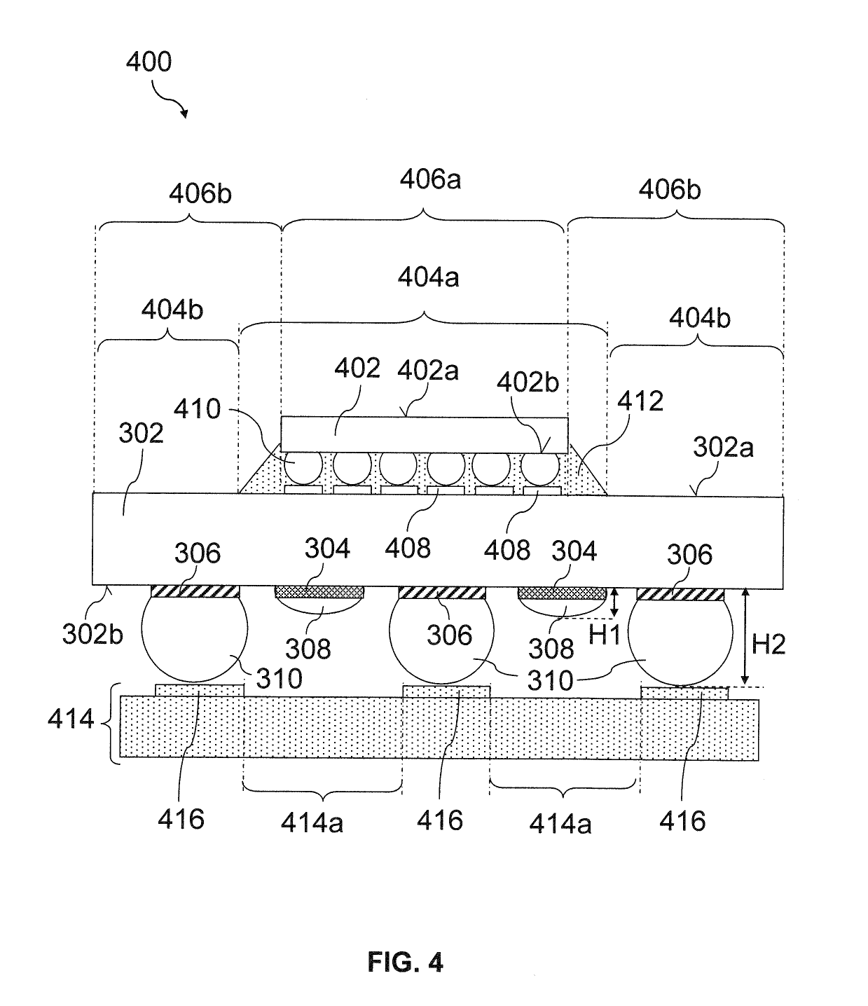

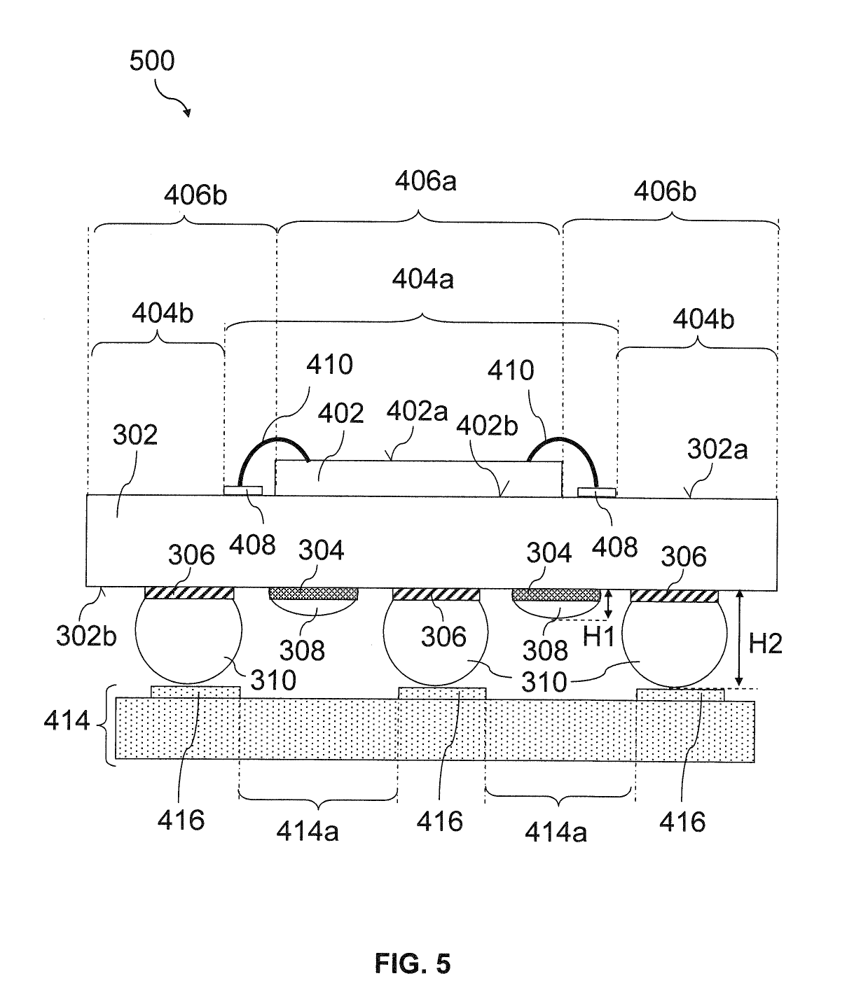

The interconnection layer 302 may have a first surface 302a and a second surface 302b opposite the first surface 302a. The first surface 302a may, for example, be a top surface of the interconnection layer 302, and the second surface 302b may, for example, be a bottom surface of the interconnection layer 302. The first surface 302a of the interconnection layer 302 may be configured to face at least one chip (not shown in FIG. 3; see description below in respect of FIG. 4 and FIG. 5).

The interconnection layer 302 may include, or may be, a carrier, for example, in a flip-chip package and/or in a wire-bonded chip package and/or in a 2.5D interposer package. By way of an example, the interconnection layer 302 may include, or may be, at least one of a silicon, glass, or organic carrier. The interconnection layer 302 may include the at least one first pad 304 and/or the at least one second pad 306 shown in FIG. 3.

The interconnection layer 302 may include, or may be, a redistribution layer (e.g. a thin film redistribution layer), for example, in a WLB package (e.g. a fan-in and/or a fan-out WLB package).

The interconnection layer 302 may include, or may be, a circuit pattern. For example, as described above, the interconnection layer 302 may include, or may be, a redistribution layer in, for example, a WLB package.

The interconnection layer 302 may include, or may be, a metal or metal alloy. The metal may include, or may consist of, at least one metal selected from a group of metals, the group consisting of: copper, nickel, palladium, silver, tin, aluminium, and gold, or an alloy containing at least one of the aforementioned metals. For example, the interconnection layer 302 may include, or may be, a leadframe (e.g. a copper leadframe).

The interconnection layer 302 may include, or may be, a material capable of supporting one or more circuit patterns (e.g. one or more printed circuit patterns). For example, one or more circuit patterns may be formed at (e.g. disposed on) the first surface 302a and/or the second surface 302b of the interconnection layer 302. For example, the at least one first pad 304 and/or the at least one second pad 306 shown in FIG. 3 may be part of one or more circuit patterns formed at the second surface 302b of the interconnection layer 302. By way of another example, one or more circuit patterns (e.g. a multi-level printed circuit pattern) may be included within (e.g. embedded in) the interconnection layer 302 (not shown in FIG. 3). In other words, one or more circuit patterns may be formed between the first surface 302a and the second surface 302b of the interconnection layer 302.

The material of the interconnection layer 302 may include, or may consist of, at least one material selected from a group of materials, the group consisting of: a ceramic material (e.g. high temperature cofired ceramics (HTCC) or low temperature cofired ceramics (LTCC)), an epoxy material, unfilled or possibly filled (e.g. with glass fibre), an imide material, a polyester material, a BT material (Bismaleimid (B) and Triazinharz (T)), a polyimide material, a prepreg, a silicon material, a glass material and a teflon material.

The interconnection layer 302 may include, or may be, a semiconductor material. The semiconductor material may include, or may consist of, at least one material selected from a group of materials, the group consisting of: silicon, germanium, gallium nitride, gallium arsenide, and silicon carbide, although other materials may be possible as well.

As shown in FIG. 3, the chip package 300 may include at least one first pad 304 and at least one second pad 306. Only two first pads 304 are shown as an example in FIG. 3, however the number of first pads 304 may be greater than two, and may, for example, be three, four, five, six, seven, eight, nine, or on the order of tens, hundreds, thousands of, or even more first pads. Similarly, only three second pads 306 are shown as an example in FIG. 3, however the number of second pads 306 may be greater than three and may, for example, be four, five, six, seven, eight, nine, or on the order of tens, hundreds of, or even more second pads.

The at least one first pad 304 and the at least one second pad 306 may be formed at one or more surfaces of the interconnection layer 302. In other words, the at least one first pad 304 and at least one second pad 306 may be formed at the first surface 302a and/or the second surface 302b of the interconnection layer 302. Stated in yet another way, the at least one first pad 304 and the at least one second pad 306 may be formed at at least one of the first surface 302a and the second surface 302b of the interconnection layer 302.

For example, the at least one first pad 304 may be formed at the second surface 302b of the interconnection layer 302, as shown in FIG. 3. Alternatively, the at least one first pad 304 may be formed at the first surface 302a of the interconnection layer 302. As a further example, the chip package 300 may include a plurality of first pads 304, which may be formed at both the first surface 302a and the second surface 302b of the interconnection layer 302.

Similarly, the at least one second pad 306 may be formed at the second surface 302b of the interconnection layer 302, as shown in FIG. 3. Alternatively, the at least one second pad 306 may be formed at the first surface 302a of the interconnection layer 302. As a further example, the chip package 300 may include a plurality of second pads 306, which may be formed at both the first surface 302a and the second surface 302b of the interconnection layer 302.

The at least one first pad 304 and/or the at least one second pad 306 formed at a surface of the interconnection layer 302 may be connected to (e.g. electrically connected to) one or more circuit patterns formed at said surface of the interconnection layer 302 and/or another surface of the interconnection layer 302 and/or within (e.g. embedded in) the interconnection layer 302. For example, the at least one first pad 304 and the at least one second pad 306 shown in FIG. 3 may be connected to one or more circuit patterns formed at (e.g. disposed on) the first surface 302a of the interconnection layer 302. By way of another example, the at least one first pad 304 and the at least one second pad 306 shown in FIG. 3 may be connected to one or more circuit patterns formed at (e.g. disposed on) the second surface 302b of the interconnection layer 302. Alternatively, or in addition to the above, the at least one first pad 304 and/or the at least one second pad 306 may be connected to one or more circuit patterns (e.g. multi-level circuit patterns) included within (e.g. embedded in) the interconnection layer 302 (not shown in FIG. 3).

The at least one first pad 304 may be a test pad (e.g. a pad configured to receive one or more test signals). The at least one first pad 304 may be configured for use in electrical testing only. For example, the at least one first pad 304 may be used for testing at least one chip that may be disposed on (e.g. mounted on) the interconnection layer 302 (e.g. on the first surface 302a of the interconnection layer 302). By way of another example, the at least one first pad 304 may be used to configure settings of at least one chip that may be disposed on the interconnection layer. However, the at least one first pad 304 may be not be used after configuring and/or testing the at least one chip (e.g. in an end-user connection). Stated differently, the at least one first pad 304 (e.g. a test pad) may not be used to exchange (e.g. to provide and/or receive) signals in an end-user connection.

The at least one first pad 304 may be a pad that may be used to exchange signals (e.g. test signals) in any stage prior to an end-user connection. Accordingly, the at least one first pad 304 may be a pad that may not be used to exchange application-specific signals (e.g. in a customer board).

The at least one second pad 306 may include, or may be, at least one pad selected from a group of pads, the group consisting of: an input/output (I/O) pad, a power supply pad (e.g. a pad configured to receive power supply potential), and a ground pad (e.g. a pad configured to receive ground potential). An I/O pad may refer to a pad that may be configured to at least exchange (e.g. to provide and/or receive) end-user signals. For example, the I/O pad may be used for exchanging application-specific signals with at least one chip disposed on the interconnection layer 302 (e.g. on the first surface 302a of the interconnection layer 302). The I/O pad may also be configured to receive one or more test signals. However, in contrast to the above-described at least one first pad 304 (e.g. a test pad), the I/O pad may also be used thereafter in an end-user connection.

The at least one first pad 304 and/or the at least one second pad 306 may include, or may consist of, a metal or metal alloy. The metal may include at least one metal selected from a group of metals, the group consisting of: copper, aluminium, nickel, palladium, titanium, chrome, tin and gold, or an alloy containing at least one of the aforementioned metals.

As shown in FIG. 3, the chip package 300 may include at least one first conductive interconnect 308 formed over the at least one first pad 304, and at least one second conductive interconnect 310 formed over the at least one second pad 306.

The at least one first conductive interconnect 308 and/or the at least one second conductive interconnect 310 may include, or may consist of, a metal or metal alloy. The metal may include at least one metal selected from a group of metals, the group consisting of: tin, copper, silver, lead, bismuth, indium, zinc, and antimony, or an alloy containing at least one of the aforementioned metals. The at least one first conductive interconnect 310 and/or the at least one second conductive interconnect 310 may include a core surrounded by one or more of the aforementioned materials. The core may include a polymer or metal. For example, the at least one first conductive interconnect 308 and/or the at least one second conductive interconnect 310 may include, or may consist of, a solder material (e.g. a Sn—Ag—Cu (Tin-Silver-Copper) alloy).

As shown in FIG. 3, a height H1 of the at least one first conductive interconnect 308 may be less than a height H2 of the at least one second conductive interconnect 310.

The height H1 of the at least one first conductive interconnect 308 may be measured in a direction perpendicular to a surface of the interconnection layer 302 over which the at least one first conductive interconnect 308 is formed. For example, the at least one first conductive interconnect 308 shown in FIG. 3 is formed over the second surface 302b of the interconnection layer 302. Accordingly, the height H1 of the at least one first conductive interconnect 308 may be measured in a direction perpendicular to the second surface 302b of the interconnection layer 302. As a further example, the at least one first conductive interconnect 308 may be formed over the first surface 302a of the interconnection layer 302 (not shown in FIG. 3). In such an example, the height H1 of the at least one first conductive interconnect 308 may be measured in a direction perpendicular to the first surface 302a of the interconnection layer 302. The height H2 of the at least one second conductive interconnect 310 may be measured in a similar manner, namely, in a direction perpendicular to a surface of the interconnection layer 302 over which the at least one second conductive interconnect 310 is formed.

The height H1 of the at least one first conductive interconnect 308 may be measured from a surface of the interconnection layer 302 over which the at least one first conductive interconnect 308 is formed to a part of the at least one first conductive interconnect 308 farthest from said surface of the interconnection layer 302. In other words, the height H1 may refer to the greatest extent of the at least one first conductive interconnect 308 in a direction perpendicular to the surface of the interconnection layer 302 over which the at least one first conductive interconnect 308 is formed. For example, the height H1 of at least one first conductive interconnect 308 shown in FIG. 3 may be measured from the second surface 302b of the interconnection layer 302 to a part of the at least one first conductive interconnect 308 farthest from the second surface 302b of the interconnection layer 302. The height H2 of the at least one second conductive interconnect 310 may be measured in a similar manner. For example, the height H2 of the at least one second conductive interconnect 310 shown in FIG. 3 may be measured from the second surface 302b of the interconnection layer 302 to a part of the at least one second conductive interconnect 310 farthest from the second surface 302b of the interconnection layer 302.

The height H1 of the at least one first conductive interconnect 308 may be in the range from about 20 μm to about 100 μm, e.g. in the range from about 25 μm to about 95 μm, e.g. in the range from about 30 μm to about 90 μm, e.g. in the range from about 40 μm to about 85 μm, e.g. in the range from about 50 μm to about 80 μm, e.g. in the range from about 60 μm to about 70 μm, although other heights H1 may be possible as well.

The height H2 of the at least one second conductive interconnect 310 may be in the range from about 200 μm to about 350 μm, e.g. in the range from about 220 μm to about 325 lam, e.g. in the range from about 230 μm to about 300 μm, e.g. in the range from about 250 μm to about 280 μm, although other heights H2 may be possible as well.

The at least one first conductive interconnect 308 may have a convex shape. For example, the at least one first conductive interconnect 308 may be shaped as a lens (e.g. a convex lens). For example, the at least one first conductive interconnect 306 may be a lens-shaped solder material formed over the at least one first pad 304, as shown in FIG. 3. By way of another example, the shape of the at least one first conductive interconnect 308 may be at least substantially spherical, for example a ball. For example, the at least one first conductive interconnect 306 may be a solder ball formed over the at least one first pad 304. In other examples, the at least one first conductive interconnect 308 may, for example, have the shape of a cylindrical pillar, a rectangular pillar, a tower, a pyramid, or a truncated cone, although other shapes may be possible as well.

A shape of the at least one second conductive interconnect 310 may, for example, be a bump. By way of another example, the shape of the at least one second conductive interconnect 310 may be at least substantially spherical, for example a ball (e.g. a solder ball) as shown in FIG. 3. In other examples, the at least one second conductive interconnect 310 may, for example, have the shape of a cylindrical pillar, a rectangular pillar, a tower, a pyramid, or a truncated cone, although other shapes may be possible as well.

Regardless of the shape of the at least one first and second conductive interconnects 308, 310, the height H1 of the at least one first conductive interconnect 308 may be less than the height H2 of the at least one second conductive interconnect 310.

Electrical testing may be performed by means of a plurality of test probes (e.g. test probes of a test card) connected to the at least one first pad 304 and, possibly, to the at least one second pad 306. The at least one first conductive interconnect 308 covering the at least one first pad 304, and the at least one second conductive interconnect 310 covering the at least one second 306 pad may include, or may consist of, a similar material. For example, the at least one first conductive interconnect 308 and the at least one second conductive interconnect may consist of a common metallization (e.g. solder material). Therefore, one or more test signals may be provided to surfaces that may include, or may consist of, similar materials. Consequently, testing may be performed on surfaces that may have substantially equal contact resistance. Therefore, an effect that may be observed in the chip package 300 may be a substantially equal contact resistance for test surfaces, which may result in a high test quality and a high measure of repeatability of testing.

As described above, the at least one first conductive interconnect 308 may be formed over the at least one first pad 304 (e.g. a test pad, for example a copper test pad). Therefore, the at least one first conductive interconnect 308 may protect the at least one first pad 304 from moisture and/or oxidation. Therefore, an effect that may be observed in the chip package 300 may be prevention of corrosion of the at least one first pad 304 (e.g. test pad), which may result in a high test quality and a high measure of repeatability of testing.

FIG. 4 shows a cross-sectional view of a chip package 400 including at least one chip 402, a chip-mounting region 404a, and a chip-external connection region 414.

Reference signs in FIG. 4 that are the same as in FIG. 3 denote the same or similar elements as in FIG. 3. Thus, those elements will not be described in detail again here; reference is made to the description above. Differences between FIG. 4 and FIG. 3 are described below.

As shown in FIG. 4, a chip package 400 may include at least one chip 402.

Only one chip 402 is shown as an example, however the number of chips 402 may be greater than one, and may, for example, be two, three, four, five, six, seven, eight, nine, or on the order of tens, hundreds, thousands of, or even more chips. For example, the chip package 400 may include a plurality of chips 402. The plurality of chips 402 may be stacked vertically, for example in SiP (System-In-Package) and/or PoP (Package-on-Package) packaging. Alternatively, or in addition to vertical stacking, a chip of the plurality of chips 402 may be placed beside another chip of the plurality of chips 402.

The at least one chip 402 may have a first chip surface 402a facing away from the first surface 302a of the interconnection layer 302, and a second chip surface 402b opposite the first chip surface 402a. Accordingly, the first surface 302a of the interconnection layer 302 may face the second chip surface 402b, as shown in FIG. 4.

The at least one chip 402 may be disposed over at least a part 406a of the first surface 302a of the interconnection layer 302. For example, the at least one chip 402 may be disposed over the part 406a of the first surface 302a of the interconnection layer 302, and another part 406b of the first surface 302a of the interconnection layer 302 may be free from the at least one chip 402, as shown in FIG. 4. Alternatively, the at least one chip 402 may be disposed over the entire first surface 302a of the interconnection layer 302, e.g. the entire first surface 302a of the interconnection layer 302 may be indicated as the part 406a of the first surface 302a of the interconnection layer 302, and the other part 406b of the first surface 302a of the interconnection layer 302 may not be present.

As shown in FIG. 4, the interconnection layer 302 may include a chip-mounting region 404a configured to connect to (e.g. electrically connected and/or coupled to) the at least one chip 402. The chip-mounting region 404a may be formed at a part of the first surface 302a of the interconnection layer 302, such that another part 404b of the first surface 302a of the interconnection layer 302 may be free from the chip-mounting region 404a, as shown in FIG. 4. Alternatively, the chip-mounting region 404a may be formed at the entire first surface 302a of the interconnection layer 302, e.g. the entire first surface 302a of the interconnection layer 302 may be indicated as chip-mounting region 404a, and the part 404b of the first surface 302a of the interconnection layer 302 may not be present. Accordingly, the chip-mounting region 404a may be formed at at least a part of the first surface 302a of the interconnection layer 302.

The chip-mounting region 404a may include at least one chip bonding pad 408 formed at the first surface 302a of the interconnection layer 302. The at least one chip bonding pad 408 may be configured to bond the at least one chip 402 to the interconnection layer 302. The at least one chip bonding pad 408 may be a part of one or more circuit patterns formed at (e.g. disposed on) the first surface 302a of the interconnection layer 302. The at least one chip bonding pad 408 may be connected to the at least one first pad 304 and/or the at least one second pad 306 by means of, for example, at least one circuit pattern (e.g. a multi-level printed circuit pattern) embedded in the interconnection layer 302.

The at least one chip bonding pad 408 may include, or may consist of, a metal or metal alloy. The metal may include at least one metal selected from a group of metals, the group consisting of: copper, aluminium, nickel and gold, or an alloy containing at least one of the aforementioned metals.

The at least one chip 402 may be bonded to the at least one chip bonding pad 408 by means of at least one chip interconnect 410. For example, the at least one chip 402 may be bonded to the at least one bonding chip pad 408 using a flip-chip packaging method, as shown in FIG. 4. Accordingly, the at least one chip interconnect 410 may include, or may be, a solder ball.

In a flip-chip packaging method, the at least one chip interconnect 410 (e.g. solder ball) may be formed at an active surface of the at least one chip 402. For example, the second chip surface 402b may be an active surface of the at least one chip 402. Accordingly, the active surface of the at least one chip 402 may face the first surface 302a of the interconnection layer 302.

An underfill 412 (e.g. a resin compound) may be interposed between the at least one chip 402 and the interconnection layer 302, as shown in FIG. 4. The chip-mounting region 404a may, for example, include the widest lateral extent of the underfill 412, as shown in FIG. 4.

As described above, the at least one first pad 304 and the at least one second pad 306 may be formed at the first surface 302a of the interconnection layer 302. In such an example, the at least one first pad 304 and the at least one second pad 306 may be formed at the part 404b of the first surface 302a of the interconnection layer 302 that is free from the chip-mounting region 404a. If the chip-mounting region 404a is formed at the entire first surface 302a of the interconnection layer 302, the at least one first pad 304 and the at least one second pad 306 may be formed at the second surface 302b of the interconnection layer 302, and the first surface 302b of the interconnection layer 302 may be free from the at least one first pad 304 and the at least one second pad 306.

The chip package 400 may include a chip-external connection region 414. The chip-external connection region 414 may include, or may be, an end-user board (e.g. a customer board), such as, for example, a board (e.g. printed circuit board) used for an end-user application (e.g. for a mobile application).

The chip-external connection region 414 may include at least one landing pad 416 configured to connect to the at least one second conductive interconnect 310 formed over the at least one second pad 306, as shown in FIG. 4.

The chip-external connection region 414 may include circuitry configured to exchange at least one of an input/output (I/O) signal (e.g. a signal other than a test signal, for example an end-user signal), a power supply potential, and a ground potential with the at least one second conductive interconnect 310. For example, circuitry may be included within (e.g. embedded in) the chip-external connection region 414, and may exchange at least one of the above-described signals with the at least one second conductive interconnect 310 using the at least one landing pad 416.

As described above, the height H1 of the at least one first conductive interconnect 308 may be less that the height H2 of the at least one second conductive interconnect 310. Therefore, the at least one first conductive interconnect 308 may not be in contact with the chip-external connection region 414.

As described above, the at least one first pad 304 may not be used in an end-user connection. Therefore, landing pads for the at least one first conductive interconnect 308 may not need to be formed at the chip-external connection region 414. Therefore, an area 414a at the chip-external connection region 414 that would have been taken up by landing pads for the at least one first conductive interconnect 308 may be free for routing (e.g. circuit routing).

Accordingly, an effect that may be observed in the chip package 400 may be increased area for routing in an end-user board, which may result in a simpler circuit design in the end-user board (e.g. less layers within customer board and/or simpler routing), which may lower the cost of production of the chip package 400.

FIG. 5 shows a cross-sectional view of a chip package 500 including at least one chip 402 and a chip-mounting region 404a.

Reference signs in FIG. 5 that are the same as in FIG. 4 denote the same or similar elements as in FIG. 4. Thus, those elements will not be described in detail again here; reference is made to the description above. Differences between FIG. 5 and FIG. 4 are described below.

As described above, the chip-mounting region 404a may include at least one chip bonding pad 408 configured to hold the at least one chip 402.

The at least one chip 402 may be bonded to the at least one chip bonding pad 408 by means of at least one chip interconnect 410. The at least one chip 402 may be bonded to the at least one chip bonding pad 408 using a wire bonding packaging method, as shown in FIG. 5. Accordingly, the at least one chip interconnect 410 may include, or may be, a wire (e.g. a metal wire, for example a gold wire). In a wire bonding packaging method, the at least one chip interconnect 410 may be formed at an active surface of the at least one chip 402. For example, the first chip surface 402a may be an active surface of the at least one chip 402. Accordingly, the active surface of the at least one chip 402 may face away from the first surface 302a of the interconnection layer 302.

Although FIG. 4 and FIG. 5 are described in relation to a flip-chip packaging method and a wire bonding packaging method, respectively, other packaging methods may be possible as well (e.g. a wafer level BGA (ball grid array) packaging method).

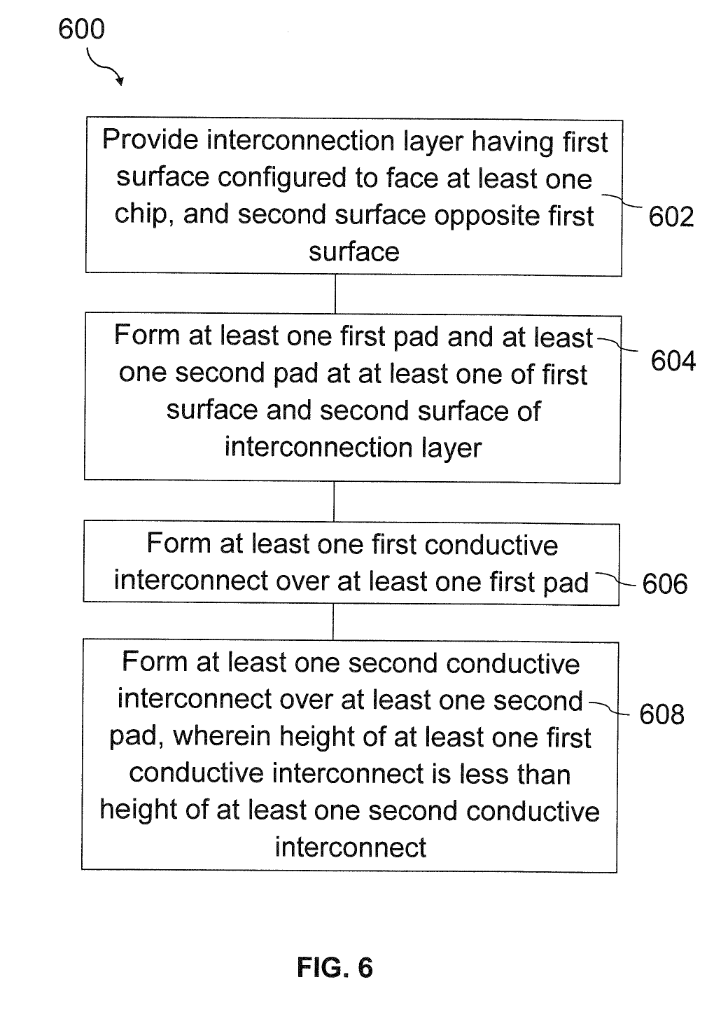

FIG. 6 shows a method 600 for manufacturing a chip package.

The method 600 may, for example, be used to manufacture the chip package 300 shown in FIG. 3.

The method 600 for manufacturing a chip package may include: providing an interconnection layer having a first surface configured to face at least one chip, and a second surface opposite the first surface (in 602); forming at least one first pad and at least one second pad at at least one of the first surface and the second surface of the interconnection layer (in 604); forming at least one first conductive interconnect over the at least one first pad (in 606); and forming at least one second conductive interconnect over the at least one second pad, wherein a height of the at least one first conductive interconnect is less than a height of the at least one second conductive interconnect (in 608).

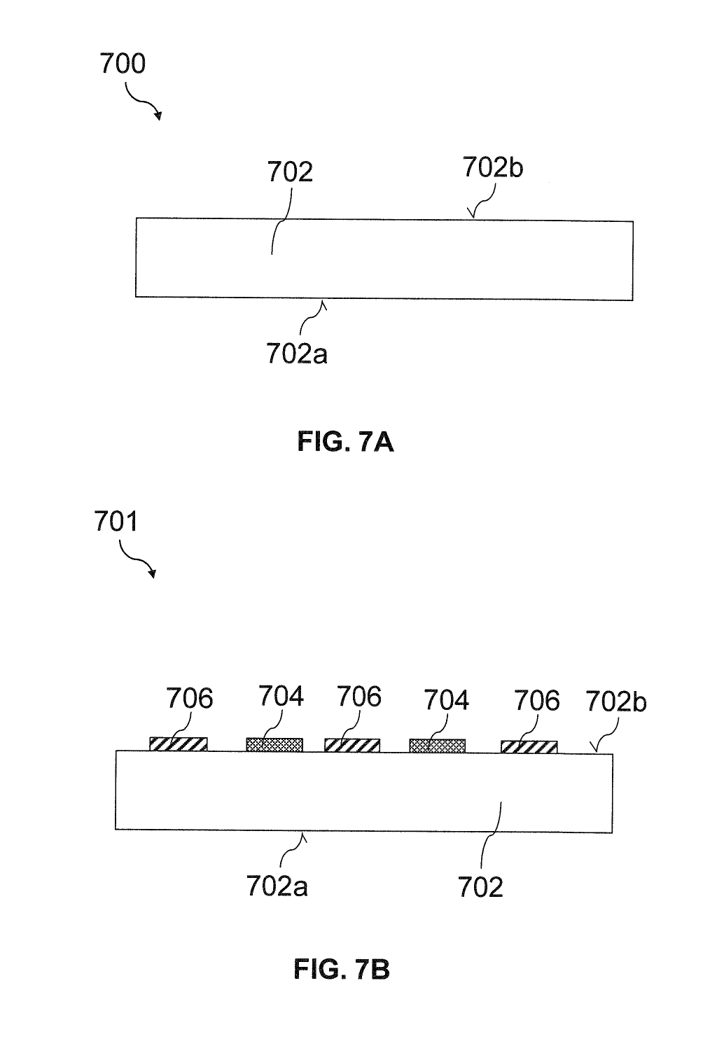

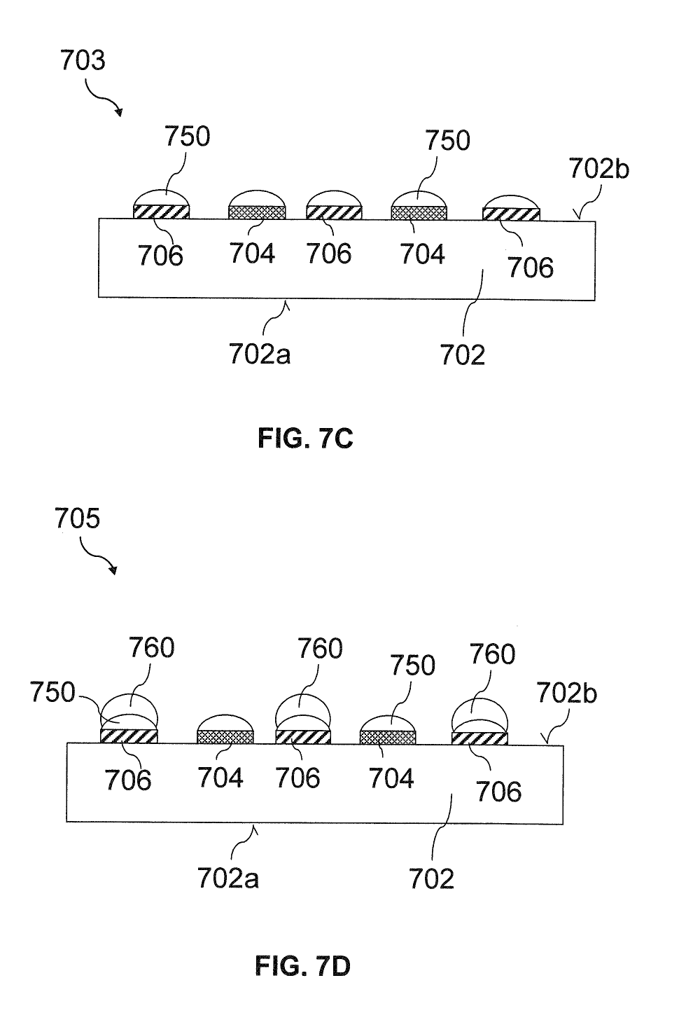

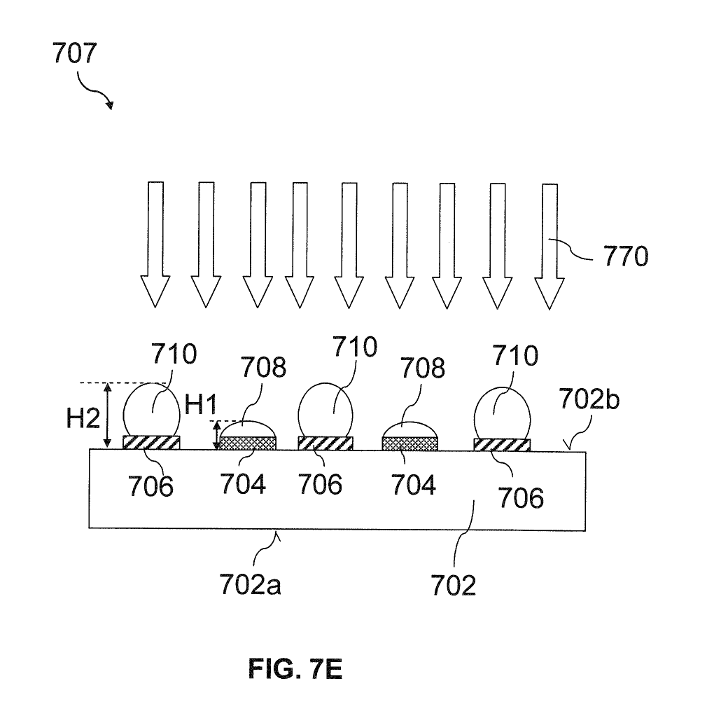

FIG. 7A to FIG. 7E show various views illustrating a method for manufacturing a chip package.

As shown in FIG. 7A in a view 700, the method for manufacturing a chip package may include providing a interconnection layer 702 having a first surface 702a configured to face at least one chip, and a second surface 702b opposite the first surface 702a. The further features described above with regards to the interconnection layer 302 having the first surface 302a and the second surface 302b shown in FIG. 3 may be equally applicable for the interconnection layer 702 having the first surface 702a and the second surface 702b shown in FIG. 7A.

As shown in FIG. 7B in a view 701, the method for manufacturing a chip package may include forming at least one first pad 704 (e.g. a test pad) and at least one second pad 706 (e.g. an I/O pad) at at least one of the first surface 702a and the second surface 702b of the interconnection layer 702. For example, FIG. 7B shows the at least one first pad 704 (e.g. a test pad) and the at least one second pad 706 (e.g. an I/O pad) formed at the second surface 702b of the interconnection layer 702.

The at least one first pad 704 and the at least one second pad 706 may be formed by means of a deposition process such as, for example, at least one of a plating process, a chemical vapor deposition (CVD) process, a low-pressure CVD (LPCVD) process, a plasma-enhanced chemical vapor deposition (PECVD) process, a high-density plasma chemical vapor deposition (HDP-CVD) process, a physical vapor deposition (PVD) process, and a sputtering process, or other suitable deposition processes.

The deposition process may be performed in conjunction with a patterned mask, which may, for example, be formed over a part of at least one of the first surface 702a and the second surface 702b of the interconnection layer 702. For example, the at least one first pad 704 and the at least one second pad 706 shown in FIG. 7B are formed on the second surface 702b of the interconnection layer 702. Accordingly, the patterned mask may be formed over a part of that second surface 702b of the interconnection layer 702. The patterned mask may be removed after forming the at least one first pad 704 and at least one second pad 706.

The further features described above with regards to the at least one first pad 304 and at least one second pad 306 shown in FIG. 3 may be equally applicable for at least one first pad 704 and at least one second pad 706 shown in FIG. 7B.

FIG. 7C to FIG. 7E show various views illustrating a method for forming at least one first conductive interconnect 708 (shown in FIG. 7E) over the at least one first pad 704, and forming at least one second conductive interconnect 710 (shown in FIG. 7E) over the at least one second pad 706.

As shown in FIG. 7C in a view 703, forming the at least one first conductive interconnect 708 and the at least one second conductive interconnect 710 may include depositing a first conductive material 750 over the at least one first pad 704 and the at least one second pad 706. For example, depositing the first conductive material 750 may include a non-selective deposition process. For example, the first conductive material 750 may be deposited over both the at least one first pad 704 (e.g. a test pad) and the at least one second pad 706 (e.g. an I/O pad).

The first conductive material 750 may include, or may be, a metal or metal alloy. The metal may include at least one metal selected from a group of metals, the group consisting of: tin, copper, silver, lead, bismuth, indium, zinc, and antimony, or an alloy containing at least one of the aforementioned metals. For example, the first conductive material 750 may include, or may consist of, a solder material (e.g. a Sn—Ag—Cu (Tin-Silver-Copper) alloy). For example, the first conductive material 750 may include, or may be, solder paste.

The first conductive material 750 may be deposited over the at least one first pad 704 and the at least one second pad 706 by means of, for example, a printing process (e.g. a solder paste printing process). For example, a stencil may be used in the printing process. The stencil used in the printing process may, for example, depend on a pitch between adjacent pads. For example, a stencil used for printing the first conductive material 750 on the at least one first pad 704 and the at least one second pad 706 having a pitch of 0.4 mm may have a thickness of about 100 μm and/or may have an opening with a diameter of about 250 μm. The aforementioned example is merely illustrative, and is not meant to be limiting; the thickness and/or the diameter of the opening of the stencil may be different in other examples.

By way of another example, the first conductive material 750 may be deposited over the at least one first pad 704 and the at least one second pad 706 by means of a solder-jetting process. By way of yet another example, the first conductive material 750 may be deposited over the at least one first pad 704 and the at least one second pad 706 by means of a dispensing process. In other examples, other suitable deposition processes may be used to deposit the first conductive material 750 over the at least one first pad 704 and the at least one second pad 706.

As shown in FIG. 7D in a view 705, a second conductive material 760 may be deposited over the first conductive material 750 over the at least one second pad 706. For example, depositing the second conductive material 760 may include a selective deposition process, for example, the second conductive material 760 may be deposited over the at least one second pad 706, and not over the at least one first pad 704. Accordingly, the at least one first pad 704 may be free from the second conductive material 760.

The second conductive material 760 may include, or may be, a metal or metal alloy. The metal may include at least one metal selected from a group of metals, the group consisting of: tin, copper, silver, bismuth, indium, zinc, and antimony, or an alloy containing at least one of the aforementioned metals. For example, the second conductive material 760 may include, or may consist of, a solder material (e.g. a Sn—Ag—Cu (Tin-Silver-Copper) alloy). For example, the second conductive material 760 may include, or may be, solder ball (e.g. a preformed solder ball).

The second conductive material 760 may be deposited over the first conductive material 750 over the at least one second pad 706 by means of at least one of a printing process (e.g. a solder paste printing process), a solder jetting process and a dispensing process, although other deposition processes may be possible as well.

The amount (e.g. dimensions) of the second conductive material 760 deposited over the first conductive material 750 over the at least one second pad 706 may depend on a pitch between adjacent pads. For example, a pitch of 0.4 mm may lead to a nominal height of about 250 μm. By way of another example, a pitch of 0.5 mm may lead to a nominal height of about 300 μm. The aforementioned examples are merely illustrative, and are not meant to be limiting.

As shown in FIG. 7D, the at least one first pad 704 may have a smaller amount of conductive material deposited over it (e.g. only the first conductive material 750) compared with the at least one second pad 706 which may have a larger amount of conductive material deposited over it (e.g. the first and second conductive materials 750, 760). Accordingly, a structure formed at the at least one first pad 704 with the first conductive material 750 may be smaller (e.g. have a lower height) than a structure formed at the at least one second pad 706 with the first conductive material 750 and the second conductive material 760.

As shown in FIG. 7E in a view 707, forming the at least one first conductive interconnect 708 may include heating (indicated by arrows 770) the first conductive material 750 to bond the first conductive material 750 to the at least one first pad 704, to form the at least one first conductive interconnect 708. FIG. 7E also illustrates that forming the at least one second conductive interconnect 710 may include heating the second conductive material 760 and the first conductive material 750 to bond the second conductive material 760 and the first conductive material 750 to the at least one second pad 706, to form the at least one second conductive interconnect 710.

Heating (indicated by arrows 770) the first conductive material 750 and the second conductive material 760 may be performed by means of at least one of a reflow process, an annealing process, a soldering process (e.g. thermosonic soldering process), although other heating processes may be possible as well.

As described above, the at least one first pad 704 may have a smaller amount of conductive material deposited over it compared with the at least one second pad 706 which may have a larger amount of conductive material deposited over it. Accordingly, a height H1 of the at least one first conductive interconnect 708 formed at the at least one first pad 704 may be less than a height H2 of the at least one second conductive interconnect 710 formed at the at least one second pad 706.

For example, the height H1 of the first conductive interconnect 708 (e.g. printed solder paste) may be in the range from about 60 μm to about 80 μm after reflow. By way of another example, the height H2 of the second conductive interconnect 710 for a pitch of about 0.4 mm may be in the range from about 220 μm to about 280 μm after reflow (e.g. in the range from about 240 μm to about 250 μm). By way of yet another example, the height H2 of the second conductive interconnect 710 for a pitch of about 0.5 mm may be in the range from about 250 μm to about 350 μm after reflow (e.g. in the range from about 280 μm to about 300 μm).

The further features described above with regards to the at least one first conductive interconnect 308 and the at least one second conductive interconnect 310 shown in FIG. 3 may be equally applicable for the at least one first conductive interconnect 708 and the at least one second conductive interconnect 710 shown in FIG. 7E.

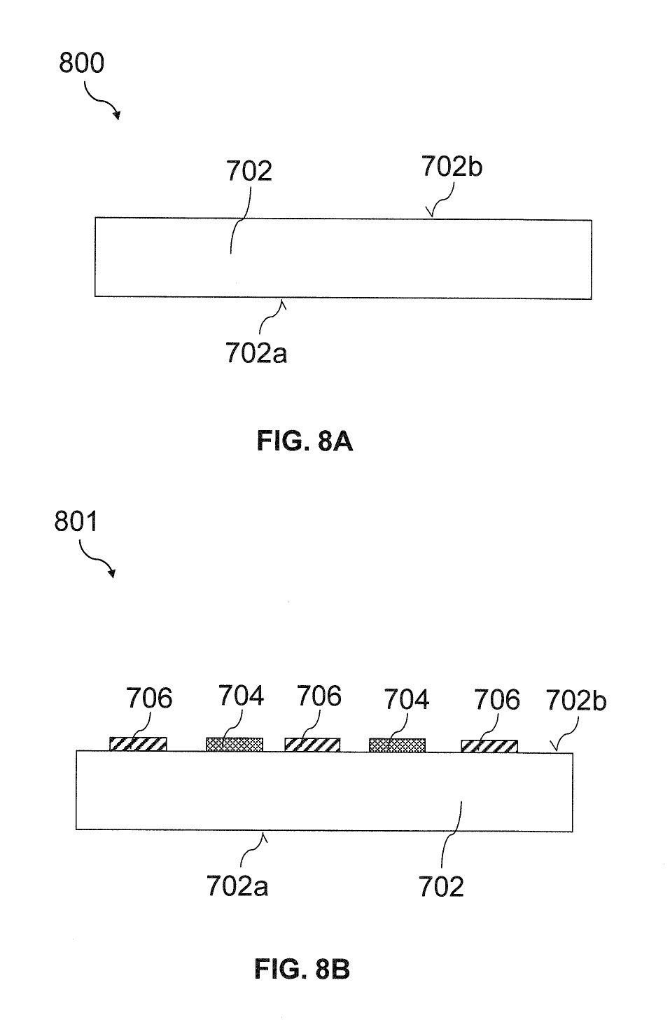

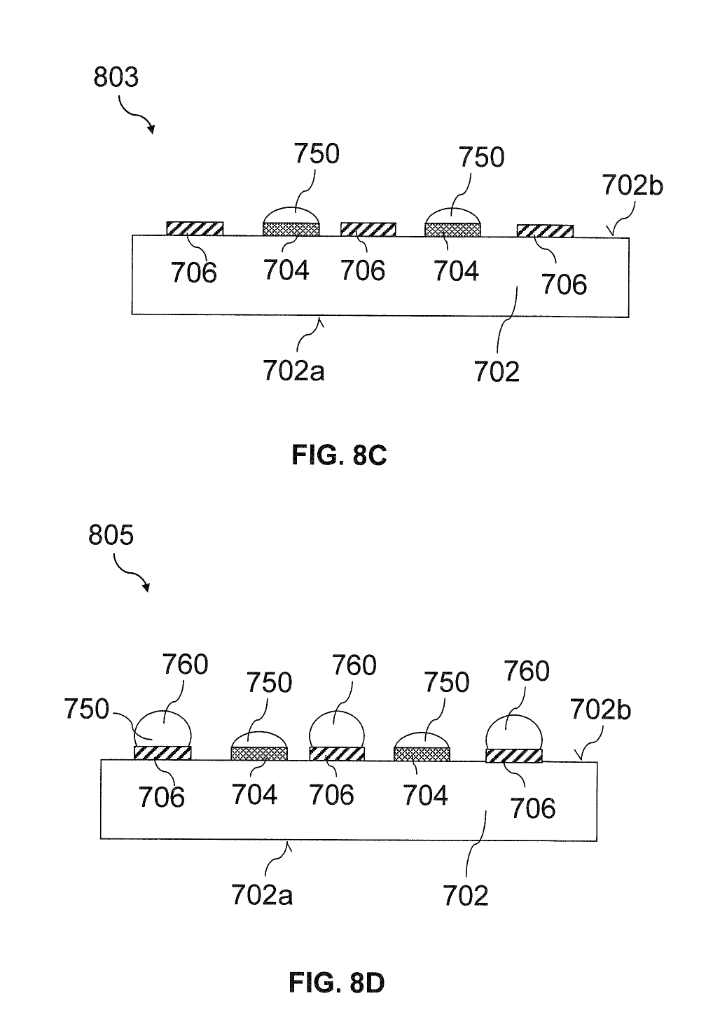

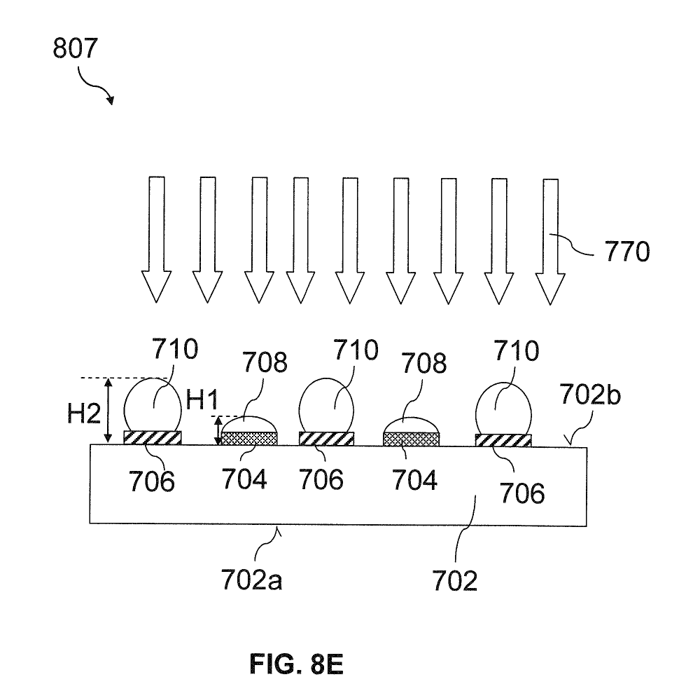

FIG. 8A to FIG. 8E show various views illustrating a method for manufacturing a chip package.

The method is to some extent similar to the method described above in connection with FIG. 7A to FIG. 7E. In particular, reference signs in FIG. 8A to FIG. 8E that are the same as in FIG. 7A to FIG. 7E denote the same or similar elements as in FIG. 7A to FIG. 7E. Thus, those elements will not be described in detail again here; reference is made to the description above.

As shown in FIG. 8A in a view 800, the method for manufacturing a chip package may include providing a interconnection layer 702 having a first surface 702a configured to face at least one chip, and a second surface 702b opposite the first surface 702a.

As shown in FIG. 8B in a view 801, the method for manufacturing a chip package may include forming at least one first pad 704 and at least one second pad 706 at at least one of the first surface 702a and the second surface 702b of the interconnection layer 702.

As shown in FIG. 8C in a view 803 forming the at least one first conductive interconnect 708 may include depositing a first conductive material 750 over the at least one first pad 704. As shown in FIG. 8C, the first conductive material 750 may be deposited selectively over the at least one first pad 704 (e.g. a test pad), and the at least one second pad 706 (e.g. an I/O pad) may be free from the first conductive material 750.

The first conductive material 750 may be deposited over the at least one first pad 704 by means of at least one of a printing process (e.g. a solder paste printing process), a solder-jetting process, and a dispensing process, although other deposition processes may be possible as well.

As shown in FIG. 8D in a view 805 forming the at least one second conductive interconnect 710 may include depositing a second conductive material 760 over the at least one second pad 706. Depositing the second conductive material 760 may include a selective deposition process. Accordingly, the at least one first pad 704 may be free from the second conductive material 760.

A volume of the first conductive material 750 may be smaller than a volume of the second conductive material 760. For example, the first conductive material 750 may include, or may be, a solder paste having a first volume, whilst the second conductive material 760 may include, or may be, a solder ball (e.g. a preformed solder ball) having a second volume. The first volume may be less than the second volume.

Therefore, the at least one first pad 704 may have a smaller amount of conductive material deposited over it compared with the at least one second pad 706 which may have a larger amount of conductive material deposited over it. Accordingly, a structure formed at the at least one first pad 704 with the first conductive material 750 may be smaller (e.g. have a lower height) than a structure formed at the at least one second pad 706 with the second conductive material 760.

As shown in FIG. 8E in a view 807, forming the at least one first conductive interconnect 708 may include heating (indicated by arrows 770) the first conductive material 750 to bond the first conductive material 750 to the at least one first pad 704, to form the at least one first conductive interconnect 708. FIG. 7E also illustrates that forming the at least one second conductive interconnect 710 may include heating the second conductive material 760 to bond the second conductive material 760 to the at least one second pad 706, to form the at least one second conductive interconnect 710. The height H1 of the at least one first conductive interconnect 708 formed at the at least one first pad 704 may be less than a height H2 of the at least one second conductive interconnect 710 formed at the at least one second pad 706.

In summary, a chip package is provided which may include: a interconnection layer having a first surface configured to face at least one chip, and a second surface opposite the first surface; at least one first pad and at least one second pad formed at at least one of the first surface and the second surface of the interconnection layer; at least one first conductive interconnect formed over the at least one first pad; and at least one second conductive interconnect formed over the at least one second pad, wherein a height of the at least one first conductive interconnect is less than a height of the at least one second conductive interconnect.

The at least one first pad may include a test pad configured to receive one or more test signals.

The at least one second pad may include at least one pad selected from a group of pads, the group consisting of: an input/output (I/O) pad, a power supply pad, and a ground pad.

The height of the at least one first conductive interconnect may be in the range from about 20 μm to about 100 μm.

The height of the at least one second conductive interconnect may be in the range from about 200 μm to about 350 μm.

At least one of the at least one first pad and the at least one second pad may include a metal or a metal alloy.

At least one of the at least one first conductive interconnect and the at least one second conductive interconnect may include a metal or a metal alloy.

At least one of the at least one first conductive interconnect and the at least one second conductive interconnect may include a solder material.

At least one of the at least one first conductive interconnect and the at least one second conductive interconnect may include a solder bump or a lens-shaped solder.

At least one of the at least one first conductive interconnect and the at least one second conductive interconnect may include a solder ball.

The interconnection layer may include a carrier.

The interconnection layer may include a redistribution layer.

The interconnection layer may include a semiconductor material.

The interconnection layer may include a leadframe.

The at least one first pad and the at least one second pad may be formed at the second surface of the interconnection layer.

The interconnection layer may include a chip-mounting region configured to connect to the at least one chip, wherein the chip-mounting region may be formed at at least a part of the first surface of the interconnection layer.

The chip package may further include at least one chip disposed over at least a part of the first surface of the interconnection layer.

An active surface of the at least one chip may face the first surface of the interconnection layer.

An active surface of the at least one chip may face away from the first surface of the interconnection layer.

The chip package may further include: a chip-external connection region, wherein the at least one second conductive interconnect may connect the carrier to the chip-external connection region.

The chip-external connection region may include at least one landing pad configured to connect the chip-external connection region to the at least one second conductive interconnect.

The chip-external connection region may include circuitry configured to exchange at least one of an input/output (I/O) signal, a power supply potential, and a ground potential with the at least one second conductive interconnect.

A method for manufacturing a chip package is provided which may include: providing a interconnection layer having a first surface configured to face at least one chip, and a second surface opposite the first surface; forming at least one first pad and at least one second pad at at least one of the first surface and the second surface of the interconnection layer; forming at least one first conductive interconnect over the at least one first pad; and forming at least one second conductive interconnect over the at least one second pad, wherein a height of the at least one first conductive interconnect is less than a height of the at least one second conductive interconnect.

Forming the at least one first conductive interconnect over the at least one first pad may include depositing a first conductive material over the at least one first pad.

The first conductive material may include a solder paste.

The first conductive material may include a metal or metal alloy.

The first conductive material may include a solder material.

Depositing the first conductive material over at least the at least one first pad may include a printing process.

Depositing the first conductive material over at least the at least one first pad may include a solder jetting process.

Forming the at least one first conductive interconnect over at the at least one first pad may further include: heating the first conductive material to bond the first conductive material to the at least one first pad.

Forming the at least one second conductive interconnect over the at least one second pad may include: depositing a first conductive material over the at least one first pad and the at least one second pad; and depositing a second conductive material over the first conductive material over the at least one second pad.

The second conductive material may include a metal or metal alloy.

The second conductive material may include a solder material.

The second conductive material may include a solder ball.

At least one of depositing the first conductive material over the at least one first pad and the at least one second pad and depositing the second conductive material over the first conductive material over the at least one second pad may include a printing process.

At least one of depositing the first conductive material over the at least one first pad and the at least one second pad and depositing the second conductive material over the first conductive material over the at least one second pad may include a solder jetting process.

Forming the at least one second conductive interconnect over the at least one second pad may further include: heating the second conductive material and the first conductive material to bond the second conductive material and the first conductive material to the at least one second pad.

Forming the at least one second conductive interconnect over the at least one second pad may include: depositing a second conductive material over the at least one second pad, wherein the at least one second pad may be free from a first conductive material.

Forming the at least one second conductive interconnect over the at least one second pad may further include: heating the second conductive material to bond the second conductive material to the at least one second pad.

While various aspects have been particularly shown and described with reference to these aspects of this disclosure, it should be understood by those skilled in the art that various changes in form and detail may be made therein without departing from the spirit and scope of the disclosure as defined by the appended claims. The scope of the disclosure is thus indicated by the appended claims and all changes which come within the meaning and range of equivalency of the claims are therefore intended to be embraced.

What is claimed is:

1. A chip package, comprising:
an interconnection layer comprising a first surface configured to face at least one chip, and a second surface opposite the first surface;
at least one first pad and at least one second pad formed on at least one of the first surface and the second surface of the interconnection layer;
at least one first conductive interconnect formed over the at least one first pad; and
at least one second conductive interconnect formed over the at least one second pad, wherein a height of the at least one first conductive interconnect is less than a height of the at least one second conductive interconnect.

2. The chip package of claim 1, wherein the at least one first pad comprises a test pad configured to receive one or more test signals.

3. The chip package of claim 1, wherein the at least one second pad comprises at least one pad selected from a group of pads, the group consisting of: an input/output (I/O) pad, a power supply pad, and a ground pad.

4. The chip package of claim 1, wherein the height of the at least one first conductive interconnect is in the range from about 20 μm to about 100 μm.

5. The chip package of claim 1, wherein the height of the at least one second conductive interconnect is in the range from about 200 μm to about 350 μm.

6. The chip package of claim 1, wherein at least one first pad, at least one second pad or a combination of at least one first pad and at least one second pad comprises a metal or a metal alloy.

7. The chip package of claim 1, wherein at least one first conductive interconnect, at least one second conductive interconnect or a combination of at least one first conductive interconnect and at least one second conductive interconnect comprises a metal or a metal alloy.

8. The chip package of claim 1, wherein at least one first conductive interconnect, at least one second conductive interconnect or a combination of at least one first conductive interconnect and at least one second conductive interconnect comprises a solder material.

9. The chip package of claim 1, wherein at least one first conductive interconnect, at least one second conductive interconnect or a combination of at least one first conductive interconnect and at least one second conductive interconnect comprises a solder bump or a lens-shaped solder.

10. The chip package of claim 1, wherein at least one first conductive interconnect, at least one second conductive interconnect or a combination of at least one first conductive interconnect and at least one second conductive interconnect comprises a solder ball.

11. The chip package of claim 1, wherein the interconnection layer comprises a carrier.

12. The chip package of claim 1, wherein the interconnection layer comprises a redistribution layer.

13. The chip package of claim 1, wherein the interconnection layer comprises a semiconductor material.

14. The chip package of claim 1, wherein the interconnection layer comprises a leadframe.

15. The chip package of claim 1, wherein the interconnection layer comprises a carrier, and wherein the at least one first pad and the at least one second pad are formed on the second surface of the interconnection layer.

16. The chip package of claim 1, wherein the interconnection layer comprises a chip-mounting region configured to be coupled to the at least one chip, wherein the chip-mounting region is formed on at least a part of the first surface of the interconnection layer.

17. The chip package of claim 1, further comprising at least one chip disposed over at least a portion of the first surface of the interconnection layer.

18. The chip package of claim 17, wherein an active surface of the at least one chip faces the portion of the first surface of the interconnection layer.

19. The chip package of claim 17, wherein an active surface of the at least one chip faces away from the portion of the first surface of the interconnection layer.

20. The chip package of claim 1, further comprising:
a chip-external connection region, wherein the at least one second conductive interconnect couples the interconnection layer to the chip-external connection region.

21. The chip package of claim 20, wherein the chip-external connection region comprises at least one landing pad configured to couple the chip-external connection region to the at least one second conductive interconnect.

22. The chip package of claim 20, wherein the chip-external connection region comprises circuitry configured to exchange at least one of an input/output (I/O) signal, a power supply potential, and a ground potential with the at least one second conductive interconnect.

23. A method for manufacturing a chip package, the method comprising:
providing an interconnection layer comprising a first surface configured to face at least one chip, and a second surface opposite the first surface;
forming at least one first pad and at least one second pad on at least one of the first surface and the second surface of the interconnection layer;
forming at least one first conductive interconnect over the at least one first pad; and
forming at least one second conductive interconnect over the at least one second pad, wherein a height of the at least one first conductive interconnect is less than a height of the at least one second conductive interconnect.

24. The method of claim 23, wherein forming the at least one first conductive interconnect over the at least one first pad comprises depositing a first conductive material over the at least one first pad.

25. The method of claim 24, wherein the first conductive material comprises a solder paste.

26. The method of claim 24, wherein the first conductive material comprises a metal or metal alloy.

27. The method of claim 24, wherein the first conductive material comprises a solder material.

28. The method of claim 24, wherein depositing the first conductive material over at least the at least one first pad comprises a printing process.

29. The method of claim 24, wherein depositing the first conductive material over at least the at least one first pad comprises a solder jetting process.

30. The method of claim 24, wherein forming the at least one first conductive interconnect over at the at least one first pad further comprises:
heating the first conductive material to bond the first conductive material to the at least one first pad.

31. The method of claim 23, wherein forming the at least one second conductive interconnect over the at least one second pad comprises:
depositing a first conductive material over the at least one first pad and the at least one second pad; and
depositing a second conductive material over the first conductive material over the at least one second pad.

32. The method of claim 31, wherein the second conductive material comprises a metal or metal alloy.

33. The method of claim 31, wherein the second conductive material comprises a solder material.

34. The method of claim 31, wherein the second conductive material comprises a solder ball.

35. The method of claim 31, wherein at least one of depositing the first conductive material over the at least one first pad and the at least one second pad and depositing the second conductive material over the first conductive material over the at least one second pad comprises a printing process.

36. The method of claim 31, wherein at least one of depositing the first conductive material over the at least one first pad and the at least one second pad and depositing the second conductive material over the first conductive material over the at least one second pad comprises a solder jetting process.

37. The method of claim 31, wherein forming the at least one second conductive interconnect over the at least one second pad further comprises:
heating the second conductive material and the first conductive material to bond the second conductive material and the first conductive material to the at least one second pad.

38. The method of claim 23, wherein forming the at least one second conductive interconnect over the at least one second pad comprises:
depositing a second conductive material over the at least one second pad, wherein the at least one second pad is free from a first conductive material.

39. The method of claim 38, wherein forming the at least one second conductive interconnect over the at least one second pad further comprises:
heating the second conductive material to bond the second conductive material to the at least one second pad.
